(19) United States
(12) Patent Application Publication
(10) Pub. No.: US 2009/0237137 A1
(43) Pub. Date: Sep. 24, 2009

(54) Flip-Flop Capable of Operating at High-Speed

(76) Inventor: Min-Su Kim, Hwaseong-si (KR)

Correspondence Address: F. CHAU & ASSOCIATES, LLC, 130 WOODBURY ROAD, WOODBURY, NY, 11797, US

(21) Appl. No.: 12/404,982

(22) Filed: Mar. 16, 2009

(30) Foreign Application Priority Data
Mar. 18, 2008 (KR) 10-2008-0024894

(51) Int. Cl. H03K 3/356; H03K 3/00

(52) U.S. Cl. 327/211; 327/199

(57) ABSTRACT

A flip-flop is provided for minimizing an input-output (D-Q) delay. The flip-flop includes a pull-up unit that receives a signal from a first node, is connected between a power voltage source and a second node, and pulls-up a voltage of the second node. A pull-down unit receives the signal from the first node, is connected between a ground voltage source and the second node, and pulls-down the voltage of the second node. A latch unit is connected to the second node and latches and outputs a signal transferred to the second node. The pull-up unit pulls-up the second node in response to one of a clock signal and a pulse signal, and the pull-down unit pulls-down the second node in response to the other one of the clock signal and the pulse signal.

### CROSS-REFERENCE TO RELATED APPLICATION

This application claims priority to and the benefit of Korean Patent Application No. 10-2008-0024894, filed on Mar. 18, 2008, in the Korean Intellectual Property Office, the entire content of which is incorporated herein by reference.

### BACKGROUND

The present disclosure relates to a flip-flop, and more particularly, to a flip-flop for minimizing an input-output (D-Q) delay.

Flip-flops store input signals in response to a clock signal or a pulse signal and sequentially transfer the input signals.

FIG. 1 is a circuit diagram illustrating a conventional master slave flip-flop 100 that is frequently used. The conventional master slave flip-flop 100 includes a master latch and a slave latch. The conventional master slave flip-flop 100 receives a data signal D and a scan input signal SI and the data signal D and the scan input signal SI are applied to a semiconductor device in response to a scan enable signal SE and an inverted scan enable signal (SEB).

The conventional master slave flip-flop 100 includes a multiplex circuit for outputting any one of the data signal D and the scan input signal SI. The multiplex circuit includes at least two AND gates 111, 112 and a NOR gate 113. The conventional master slave flip-flop 100 includes a master latch having at least one inverter 122 and tri-state inverters 121, 123 and a slave latch having at least one inverter 125 and tri-state inverters 124, 126 in order to latch and output a signal output from the multiplex circuit. The conventional master slave flip-flop 100 further includes an output buffer 127 for outputting the latched signal to the outside, in addition to the master latch and the slave latch.

However, the conventional master slave flip-flop 100 having the above-described structure is not very suitable for high speed applications since it increases an input-output (D-Q) delay. When the conventional master slave flip-flop 100 is connected to an output of a dynamic circuit, the conventional master slave flip-flop 100 receives a signal of an output terminal of the dynamic circuit. In this case, the output terminal of the dynamic circuit is pre-charged during a pre-charging period or is increased or decreased to a predetermined value during an evaluation period, and then when the conventional master slave flip-flop 100 receives the evaluated signal, the timing of the evaluation is important to the performance of the flip-flop 100 In more detail, when the output terminal of the dynamic circuit is completely evaluated after a clock signal provided to the conventional master slave flip-flop 100 is transited, the conventional master slave flip-flop 100 does not normally latch data, which causes a problem in terms of the functionality of a semiconductor chip including the conventional master slave flip-flop 100.

### SUMMARY

According to an exemplary embodiment of the present invention, there is provided a flip-flop having a pull-up unit that receives a signal from a first node, connected between a power voltage source and a second node, and that pulls-up a voltage of the second node. A pull-down unit receives the signal from the first node, is connected between a ground voltage source and the second node, and pulls-down the voltage of the second node. A latch unit is connected to the second node and latches and outputs a signal transferred to the second node. The pull-up unit pulls-up the second node in response to one of a clock signal and a pulse signal, and the pull-down unit pulls-down the second node in response to the other one of the clock signal and the pulse signal.

The flip-flop may further include an output buffer that receives the signal of the second node, generates an output signal, and provides the output signal to the outside.

The flip-flop may further include a pulse generating unit that generates the pulse signal provided to any one of the pull-up unit and the pull-down unit.

The pulse signal may be generated by using a reference clock and has the same cycle as the clock signal.

The flip-flop may be electrically connected to an external dynamic logic circuit and the first node is a pre-charged node of the external dynamic logic circuit.

The pull-up unit may include a first p-type metal-oxide-semiconductor (PMOS) transistor that operates in response to the signal received from the first node. A second PMOS transistor operates in response to the clock signal and is serially connected to the first PMOS transistor.

The pull-down unit may include a first n-type metal-oxide-semiconductor (NMOS) transistor that operates in response to the signal received from the first node. A second NMOS transistor operates in response to the pulse signal and is serially connected to the first NMOS transistor.

If the first node outputs a logic high signal, the pull-down unit may pull-down the second node in response to the signal output by the first node and a logic high state of the pulse signal, and if the first node outputs a logic low signal, the pull-up unit may pull-up the second node in response to the signal output by the first node and a logic low state of the clock signal.

According to another exemplary embodiment of the present invention, there is provided a flip-flop having a first PMOS transistor connected to a power voltage source and operating in response to a first control signal. A first NMOS transistor is connected to a ground voltage source and operates in response to a second control signal. A logic circuit is connected between the first PMOS transistor and the first NMOS transistor, receives at least one data signal and performs a logic operation with regard to the at least one data signal, and outputs a logic operation result to a first node. A latch unit is connected to the first node and latches and outputs a signal transferred to the first node. The logic operation result is provided to the first node based upon a state of the first control signal and the second control signal, where one of the first control signal and the second control signal is a clock signal and the other one of the first control signal and the second control signal is a pulse signal.

The logic circuit may include at least one PMOS transistor connected between the power voltage source and the first node and controlled by the at least one data signal. At least one NMOS transistor may be connected between the ground voltage source and the first node and be controlled by the at least one data signal.

According to another exemplary embodiment of the present invention there is provided a flip-flop having a pull-up unit that includes a first PMOS transistor which receives a signal from a first node, is connected between a power voltage source and a second node, and pulls-up a voltage of the second node. A pull-down unit includes a first NMOS transistor which receives the signal from the first node, is connected between a ground voltage source and the second node, and pulls-down the voltage of the second node. A latch unit is connected to the second node and latches and outputs a signal transferred to the second node. One of the pull-up unit and the pull-down unit pulls-up or pulls-down the second node in response to a first clock signal during a predetermined pulse period, and the other one of the pull-up unit and the pull-down unit pulls-up or pulls-down the second node in response to a second clock signal generated based upon the first clock signal.

### BRIEF DESCRIPTION OF THE DRAWINGS

FIG. 1 is a circuit diagram illustrating a conventional master slave flip-flop.

FIG. 2 is a block circuit diagram of a flip-flop according to an exemplary embodiment of the present invention.

FIG. 3 is a circuit diagram of the flip-flop shown in FIG. 2.

FIG. 4 is a circuit diagram of a pulse generating unit that generates a pulse signal shown in FIG. 2.

FIG. 5 is a waveform illustrating an operation of the flip-flop shown in FIG. 3 of receiving a logic high signal from a first node.

FIG. 6 is a waveform illustrating an operation of the flip-flop shown in FIG. 3 of receiving a logic low signal from the first node.

FIG. 7 is a waveform illustrating an operation of the flip-flop in FIG. 3 of receiving a logic low signal from the first node according to another exemplary embodiment of the present invention.

FIG. 8 is a waveform illustrating an operation of the flip-flop in FIG. 3 of receiving a logic low signal from the first node according to another exemplary embodiment of the present invention.

FIG. 9 is a circuit diagram of a flip-flop according to another exemplary embodiment of the present invention.

FIG. 10 is a circuit diagram of a flip-flop according to another exemplary embodiment of the present invention;

FIG. 11 is a circuit diagram of a flip-flop according to another exemplary embodiment of the present invention.

FIGS. 12A and 12B are circuit diagrams of a flip-flop according to another embodiment of the present invention.

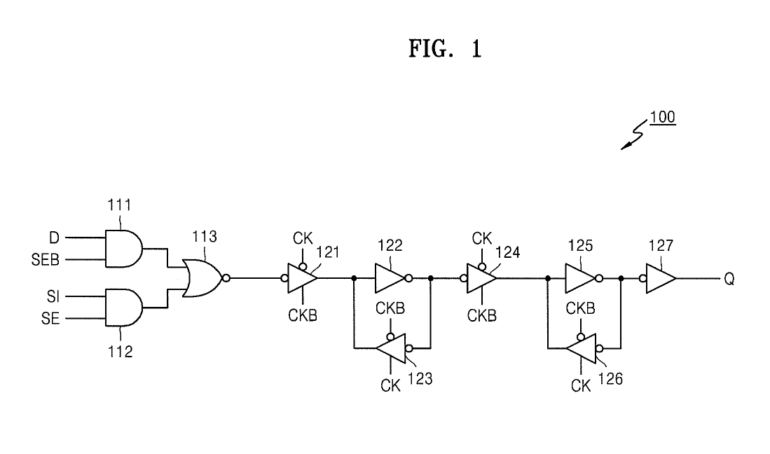

### DETAILED DESCRIPTION OF THE EMBODIMENTS

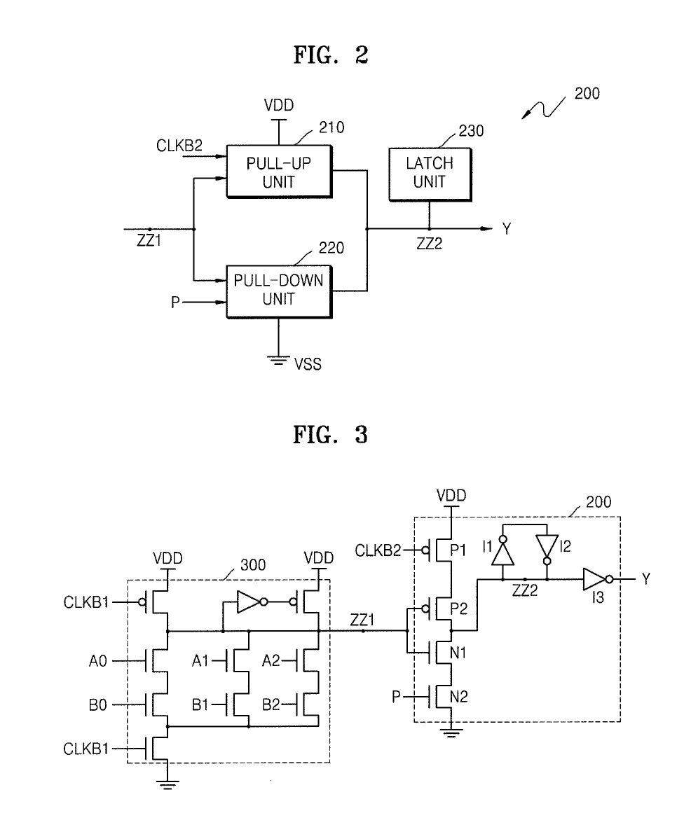

Referring now to FIG. 2, the flip-flop 200 includes a pull-up unit 210, a pull-down unit 220, and a latch unit 230. The flip-flop 200 receives a signal from a first node ZZ1, transfers the signal to a second node ZZ2, and latches and outputs the signal transferred to the second node ZZ2. In particular, the flip-flop 200 transfers the signal received from the first node ZZ1 to the second node ZZ2 in response to a clock signal CLKB2 and a pulse signal P.

The flip-flop 200 may be connected to a predetermined dynamic circuit, and receive a signal of a pre-charge node of the dynamic circuit as an input signal. In this case, the first node ZZ1 is the pre-charge node of the dynamic circuit. The flip-flop 200 may receive a reference clock signal (not shown), and may generate the clock signal CLKB2 and the pulse signal P based upon the reference clock signal.

The pull-up unit 210 receives the signal from the first node ZZ1. The pull-up unit 210 is connected between a power voltage source VDD and the second node ZZ2, and pulls-up the second node ZZ2. The pull-down unit 220 also receives the signal from the first node ZZ1. The pull-down unit 220 is connected between a ground voltage source VSS and the second node ZZ2, and pulls-down the second node ZZ2. The latch unit 230 is connected to the second node ZZ2 and latches a signal received from the pulled-up or pulled-down second node ZZ2. The latched signal is provided to the outside as an output signal Y of the flip-flop 200.

In particular, the flip-flop 200 receives the signal from the first node ZZ1 and transfers the signal to the second node ZZ2 in response to the clock signal CLKB2 and the pulse signal P. For example, the pull-up unit 210 transfers the signal received from the first node ZZ1 to the second node ZZ2 in response to any one of the clock signal CLKB2 and the pulse signal P. The pull-down unit 220 transfers the signal received from the first node ZZ1 to the second node ZZ2 in response to another one of the clock signal CLKB2 and the pulse signal P. For example, the pull-up unit 210 transfers the signal received from the first node ZZ1 to the second node ZZ2 in response to the clock signal CLKB2, and the pull-down unit 220 transfers the signal received from the first node ZZ1 to the second node ZZ2 in response to the pulse signal P.

FIG. 3 is a circuit diagram showing the flip-flop 200 of FIG. 2 coupled to a dynamic circuit 300. The pull-up unit 210 of the flip-flop 200 may include two or more p-type metal-oxide-semiconductor (PMOS) transistors. For example, the pull-up unit 210 may include a PMOS transistor P1 that operates by receiving the clock signal CLKB2 and another PMOS transistor P2 that operates by receiving the signal from the first node ZZ1. The PMOS transistors P1, P2 are serially connected between the power voltage source VDD and the second node ZZ2.

The pull-down unit 220 of the flip-flop 200 may include two or more n-type metal-oxide-semiconductor (NMOS) transistors. For example, the pull-down unit 220 may include an NMOS transistor N1 that operates by receiving the signal from the first node ZZ1 and another NMOS transistor N2 that operates by receiving the pulse signal P. The NMOS transistors N1, N2 are serially connected between the ground voltage source VSS and the second node ZZ2.

The latch unit 230 of the flip-flop 200 may include two or more inverters I1, I2. The latch unit 230 is connected to the second node ZZ2, and latches the signal transferred to the second node ZZ2. The flip-flop 200 may further include an output buffer for the signal received from the second node ZZ2 to the outside. For example, an inverter 13 receives the signal from the second node ZZ2 and generates the output signal Y.

The dynamic circuit 300 that can be connected to an input end of the flip-flop 200 sends a resultant signal according to two or more data signals A0, A1, A2, B0, B1, B2 to the first node ZZ1. The resultant signal is sent to the first node ZZ1 in response to a predetermined clock signal CLKB1 provided to the dynamic circuit 300. Also, according to the state of the data signals A0, A1, A2, B0, B1, B2, the signal of the first node ZZ1 which is pre-charged can be provided as the resultant signal or the signal of the first node ZZ1 which is evaluated can be provided as the resultant signal. The clock signal CLKB2 provided to the flip-flop 200 and the clock signal CLKB1 provided to the dynamic circuit 300 may be the same, and may have a uniform phase difference.

Although the latch unit 230 includes the two or more inverters I1, I2 in order to store the signal received from the second node ZZ2 in the present embodiment, the latch unit 230 is not limited thereto and can be modified in various ways. For example, the latch unit 230 may include a tri-state buffer or a transmission gate. The latch unit 230 may use a keeper including a PMOS transistor and an NMOS transistor. The latch unit 230 may depend on a parasitic capacitance existing in the second node ZZ2 in order to store the signal received from the second node ZZ2, and thus may not need to use an additional circuit. The output buffer that generates the output signal Y may be realized as a general static logic circuit.

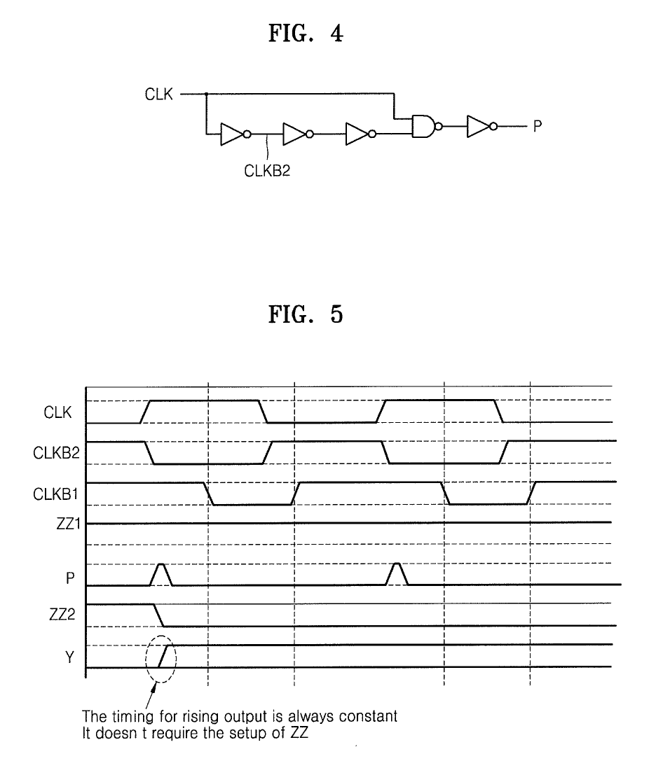

FIG. 4 is a circuit diagram of a pulse generating unit that generates the pulse signal P shown in FIG. 2. The flip-flop 200 receives the reference clock signal CLK, generates the pulse signal P provided to the pull-down unit 220 by using the reference clock signal CLK, and generates the clock signal CLKB2 provided from the pull-up unit 210. The pulse signal P may have the same cycle as the reference clock signal CLK. The pulse generating unit may be realized by using at least one inverter and a NAND gate, and may be included in the flip-flop 200.

In the flip-flop 200 shown in FIG. 3, the pull-up unit 210 includes two PMOS stacks, and operates in response to one of the clock signal CLKB2 and the pulse signal P, and the pull-down unit 220 includes two NMOS stacks, and operates in response to the other one of the clock signal CLKB2 and the pulse signal P. Owing to the above-described structure of the flip-flop 200, the flip-flop 200 can transfer a logic high signal received from the first node ZZ1 through the NMOS stacks and a logic low signal received from the first node ZZ1 through the PMOS stacks at a higher speed than a flip-flop having a conventional master slave structure. When the flip-flop 200 receives a falling signal from the first node ZZ1, which is a timing-critical signal, although the first node ZZ1 is completely evaluated after the clock signal CLKB2 or the pulse signal P is edge-triggered, the flip-flop 200 can stably receive the falling signal from the first node ZZ1.

The detailed operation of the flip-flop 200 will now be described with reference to FIGS. 5 through 8.

FIG. 5 is a waveform illustrating an operation of the flip-flop 200 when receiving a logic high signal from the first node ZZ1 according to an exemplary embodiment of the present invention. The first node ZZ1 is stabilized by a pre-charging operation of a dynamic logic circuit before the flip-flop 200 is edge-triggered, and has a logic high value. The pulse signal P may be generated by using the reference clock signal CLK. The logic high signal received from the first node ZZ1 is stored in the flip-flop 200 in response to the pulse signal P. In more detail, a discharging path of the second node ZZ2 is formed while the logic high signal received from the first node ZZ1 and the pulse signal P are activated, so that the second node ZZ2 has a logic low value. Thus, the output signal Y has the logic high value.

Although the clock signal CLKB2 has the logic low value, the first node ZZ1 already has the logic high value and the dynamic logic circuit is additionally pre-charged. Thus, the PMOS transistor P2 included in the pull-up unit 210 is turned off, the second node ZZ2 is not pre-charged to the logic high value within a cycle of the flip-flop 200 and maintains the logic low value.

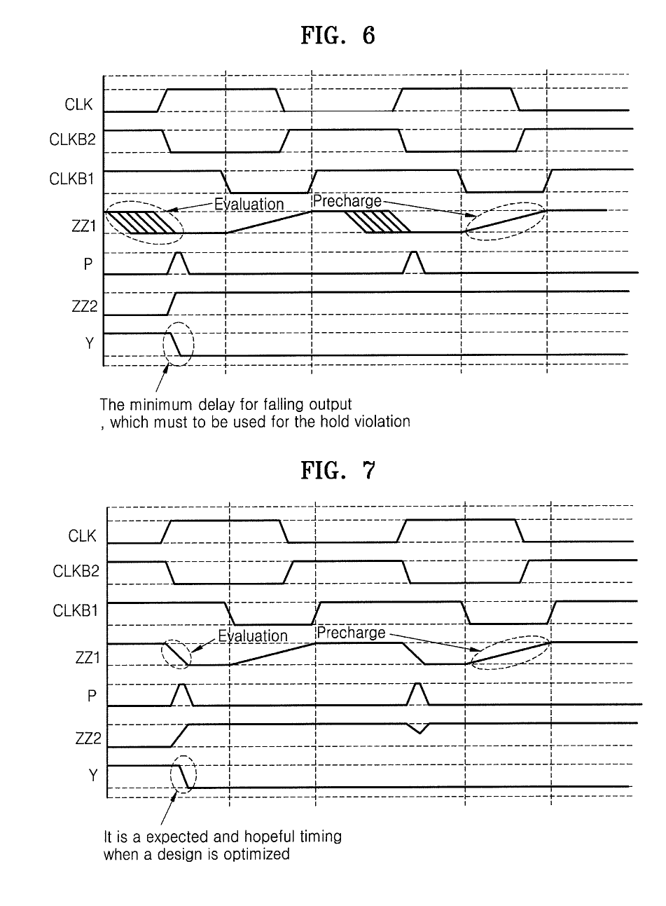

FIG. 6 is a waveform illustrating the operation of the flip-flop 200 when receiving a logic low signal from the first node ZZ1 according to an exemplary embodiment of the present invention. The flip-flop 200 receives the signal from the first node ZZ1 when the first node ZZ1 is stably evaluated before the flip-flop 200 is edge-triggered.

A falling signal received from the first node ZZ1 is generated by evaluating a dynamic circuit after the first node ZZ1 is pre-charged, and is a timing-critical signal. When the dynamic circuit is stably evaluated owing to a sufficient timing margin before the flip-flop 200 is edge-triggered (for example, the clock signal CLKB2 is edge-triggered), the flip-flop 200 stores a logic low signal received from the first node ZZ1 in response to the clock signal CLKB2. In more detail, the pull-up unit 210 of the flip-flop 200 is activated in response to the logic low signal received from the first node ZZ1 and the clock signal CLKB2 so that the second node ZZ2 has a logic high value. Thus, the output signal Y has a logic low value.

After a signal of the evaluated first node ZZ1 is stored in the flip-flop 200, although the first node ZZ1 is pre-charged again by a transition of the clock signal CLKB1 to a low level and has the logic high value, since the pulse signal P maintains a logic low value, the NMOS transistor N2 of the pull-down unit 220 remains in an OFF state. Thus, the second node ZZ2 is not discharged again during a cycle and maintains the logic high value.

FIG. 7 is a waveform illustrating the operation of the flip-flop 200 when receiving a logic low signal from the first node ZZ1 according to another exemplary embodiment of the present invention. The flip-flop 200 receives the signal from the first node ZZ1 while the first node ZZ1 is currently being evaluated when the flip-flop 200 is edge-triggered.

In this case, if the first node ZZ1 has a logic low value after being evaluated, the pull-up unit 210 of the flip-flop 200 is activated in response to the logic low signal received from the first node ZZ1 and the clock signal CLKB2 so that the second node ZZ2 has a logic high value. Thus, the output signal Y has a logic low value.

A small glitch may occur in the second node ZZ2 due to the signal received from the first node ZZ1 that is being evaluated and activation of the pulse signal P in a next cycle of the flip-flop 200. However, the output signal Y of the flip-flop 200 generally has a normal logic low value.

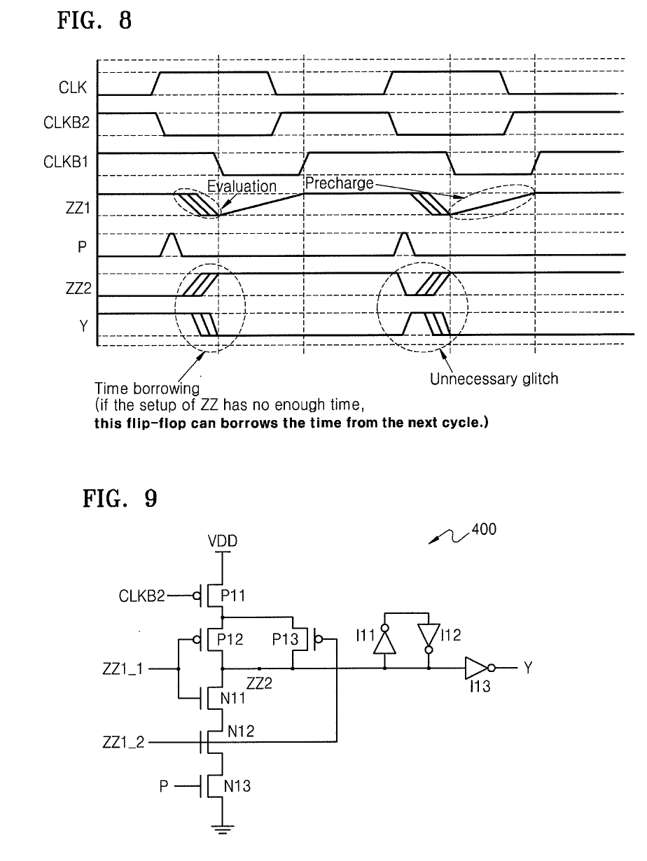

FIG. 8 is a waveform illustrating the operation of the flip-flop 200 when receiving a logic low signal from the first node ZZ1 according to another exemplary embodiment of the present invention. Referring to FIG. 7, the flip-flop 200 receives the signal from the first node ZZ1 when the first node ZZ1 is completely evaluated after the flip-flop 200 is edge-triggered. The conventional flip-flop causes a set-up violation.

Referring to FIG. 8, if the first node ZZ1 has a logic low value after being evaluated, although the first node ZZ1 is completely evaluated after the flip-flop 200 is edge-triggered, the pull-up unit 210 of the flip-flop 200 is activated in response to the signal received from the evaluated first node ZZ1 and the clock signal CLKB2, so that the second node ZZ2 has a logic high value. Thus, the output signal Y has a logic low value.

However, in this case, a small glitch may occur in the second node ZZ2 due to the signal received from the first node ZZ1 that is pre-charged and activation of the pulse signal P in a next cycle of the flip-flop 200, which increases unnecessary power consumption. However, even if the dynamic circuit does not obtain enough setup time, since the flip-flop 200 connected to the dynamic circuit may normally store and output a signal, a setup violation or a malfunction of a chip may be prevented.

FIG. 9 is a circuit diagram of a flip-flop 400 according to another exemplary embodiment of the present invention. The flip-flop 400 receives a signal output from two or more dynamic circuits. For example, the flip-flop 400 receives a first signal ZZ1_1 from a first dynamic circuit (not shown) and receives a second signal ZZ1_1 from a second dynamic circuit (not shown).

The flip-flop 400 may include an additional circuit for performing another function in addition to storing and outputting an input signal. For example, the additional circuit receives a plurality of data signals in response to the clock signal CLKB2 or the pulse signal P, and transfers a logic operation result of the data signals to the second node ZZ2. The logic operation result transferred to the second node ZZ2 is latched by a latch unit including two or more inverters 11 and 112, and provides the latched logic operation result to the outside as the output signal Y via a predetermined output buffer 113. In the present embodiment, the flip-flop 400 includes at least one transistor P12, P13, N11, N12 for performing a NAND operation with respect to the first signal ZZ1_1 and the second signal ZZ1_2.

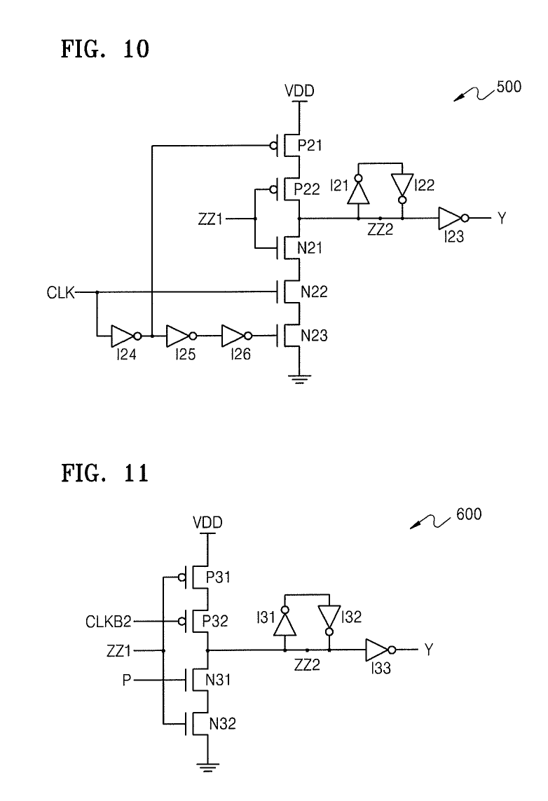

FIG. 10 is a circuit diagram of a flip-flop 500 according to another exemplary embodiment of the present invention. The flip-flop 500 includes a combination of a circuit for performing an actual flip-flop operation and a pulse generating unit for generating a pulse, thereby reducing the number of elements required to realize the flip-flop 500.

For example, the pulse generating unit may be combined with the pull-up unit 210 of the flip-flop 200 shown in FIG. 2 or the pull-down unit 220 thereof. The flip-flop 500 includes a pull-down unit combined with the pulse generating unit. Such a combination of the pulse generating unit and the pull-up unit or another circuit can be easily realized from the circuit shown in FIG. 10 and thus a detailed description thereof will now be provided.

The flip-flop 500 includes a pull-up unit for pulling-up the second node ZZ2 and a pull-down unit for pulling-down the second node ZZ2. The pull-up unit includes a PMOS transistor P21 that operates in response to a clock signal and a PMOS transistor P22 that operates in response to a signal received from the first node ZZ1. The pull-down unit includes an NMOS transistor N21 that operates in response to the signal received from the first node ZZZ1 and NMOS transistors N22, N23 that form a discharging path of the second node ZZ2 during a predetermined pulse period.

For example, in order to respond to the pulse signal P generated by a pulse generator shown in FIG. 4 during the predetermined pulse period, the NMOS transistor N22 of the pull-down unit operates in response to the reference clock signal CLK and the NMOS transistor N23 thereof operates in response to a signal for inverting and delaying the reference clock signal CLK. The pull-down unit further includes at least one inverter 124, 125, 126 that generates a signal for receiving, inverting, and delaying the reference clock signal CLK.

FIG. 11 is a circuit diagram of a flip-flop 600 according to another exemplary embodiment of the present invention. Referring to FIG. 11, the flip-flop 600 includes a pull-up unit having a PMOS stack structure and a pull-down unit having an NMOS stack structure. The pull-up unit and/or the pull-down unit can have various modifications made to the PMOS stack structure and/or the NMOS stack structure, respectively. As compared to the flip-flop 200 shown in FIG. 3, the pull-up unit of the flip-flop 600 has changed stack positions of the PMOS transistor for receiving a signal from the first node ZZ1 and a PMOS transistor for receiving the clock signal CLKB2. As compared to the flip-flop 200 shown in FIG. 3, the pull-down unit of the flip-flop 600 has changed stack positions of the NMOS transistor for receiving the signal from the first node ZZ1 and a PMOS transistor for receiving the pulse signal P.

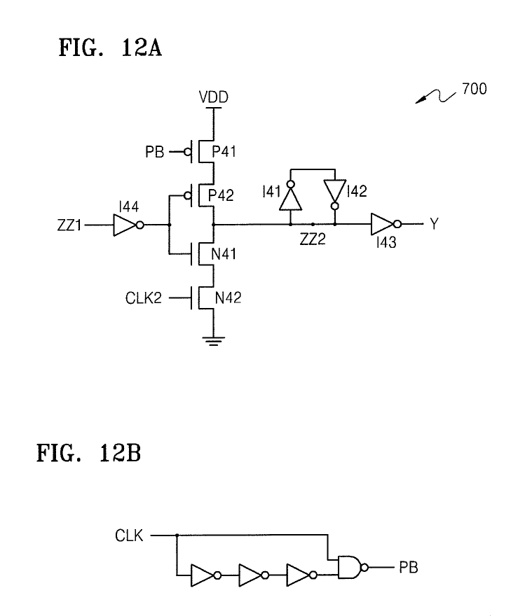

FIGS. 12A and 12B are circuit diagrams of a flip-flop 700 according to another exemplary embodiment of the present invention. Referring to FIG. 12A, the flip-flop 700 further includes a logic circuit between the first node ZZ1 and a pull-up unit and a pull-down unit. For example, the logic circuit includes an inverter 144 between the first node ZZ1 and a pull-up unit and a pull-down unit. The logic circuit may have various modifications made thereto in addition to the inverter 144.

In order to operate the flip-flop 700 that further includes the inverter 144 at an input end in the same manner as the flip-flop 200 shown in FIG. 3, signals are modified for controlling the pull-up unit and the pull-down unit. For example, the pull-up unit shown in FIG. 3 operates in response to the clock signal CLKB2, whereas a PMOS transistor P41 of the pull-up unit of the flip-flop 700 operates in response to an inverted pulse signal PB. Also, the pull-down unit shown in FIG. 3 operates in response to the pulse signal P, whereas an NMOS transistor N42 of the pull-down unit of the flip-flop 700 operates in response to an inverted clock signal CLK2. Referring to FIG. 12B, a pulse generating unit for generating the inverted pulse signal PB and the inverted clock signal CLK2 that are used in the flip-flop 700 may be included in the flip-flop 700.

While exemplary embodiments of the present have been particularly shown and described, it will be understood that various changes in form and details may be made therein without departing from the spirit and scope of the following claims.

What is claimed is:

1. A flip-flop comprising:
a pull-up unit that receives a signal from a first node, is connected between a power voltage source and a second node, and pulls-up a voltage of the second node;
a pull-down unit that receives the signal from the first node, is connected between a ground voltage source and the second node, and pulls-down the voltage of the second node; and
a latch unit that is connected to the second node and latches and outputs a signal transferred to the second node,
wherein the pull-up unit pulls-up the second node in response to one of a clock signal and a pulse signal, and the pull-down unit pulls-down the second node in response to the other one of the clock signal and the pulse signal.

2. The flip-flop of claim 1, further comprising an output buffer that receives the signal of the second node and generates an output signal.

3. The flip-flop of claim 1, further comprising a pulse generating unit that generates the pulse signal provided to either one of the pull-up unit and the pull-down unit.

4. The flip-flop of claim 3, wherein the pulse signal is generated using a reference clock and has the same cycle as the clock signal.

5. The flip-flop of claim 1, wherein the flip-flop is electrically connected to an external dynamic logic circuit and the first node is a pre-charged node of the external dynamic logic circuit.

6. The flip-flop of claim 1, wherein the pull-up unit comprises:
a first p-type metal-oxide-semiconductor (PMOS) transistor that operates in response to the signal received from the first node; and
a second PMOS transistor that operates in response to the clock signal and is serially connected to the first PMOS transistor.

7. The flip-flop of claim 6, wherein the pull-down unit comprises:
a first n-type metal-oxide-semiconductor (NMOS) transistor that operates in response to the signal received from the first node; and
a second NMOS transistor that operates in response to the pulse signal and is serially connected to the first NMOS transistor.

8. The flip-flop of claim 7, wherein, if the first node outputs a logic high signal, the pull-down unit pulls-down the second node in response to the signal output by the first node and a logic high state of the pulse signal, and
if the first node outputs a logic low signal, the pull-up unit pulls-up the second node in response to the signal output by the first node and a logic low state of the clock signal.

9. A flip-flop comprising:
a first p-type metal-oxide-semiconductor (PMOS) transistor connected to a power voltage source and that operates in response to a first control signal;
a first n-type metal-oxide-semiconductor (NMOS) transistor connected to a ground voltage source and that operates in response to a second control signal;
a logic circuit, connected between the first PMOS transistor and the first NMOS transistor, that receives at least one data signal, that performs a logic operation with regard to the at least one data signal, and that outputs a logic operation result to a first node; and
a latch unit connected to the first node that latches and outputs a signal transferred to the first node,
wherein the logic operation result is provided to the first node based upon a state of the first control signal and the second control signal, and
wherein one of the first control signal and the second control signal is a clock signal and the other one of the first control signal and the second control signal is a pulse signal.

10. The flip-flop of claim 9, wherein the logic circuit comprises:
at least one PMOS transistor connected between the power voltage source and the first node and controlled by the at least one data signal; and
at least one NMOS transistor connected between the ground voltage source and the first node and controlled by the at least one data signal.

11. A flip-flop comprising:
a pull-up unit having a first p-type metal-oxide-semiconductor (PMOS) transistor that receives a signal from a first node, is connected between a power voltage source and a second node, and that pulls-up a voltage of the second node;
a pull-down unit having a first n-type metal-oxide-semiconductor (NMOS) transistor that receives the signal from the first node, is connected between a ground voltage source and the second node, and that pulls-down the voltage of the second node; and
a latch unit connected to the second node that latches and outputs a signal transferred to the second node,
wherein one of the pull-up unit and the pull-down unit pulls-up or pulls-down the second node in response to a first clock signal during a predetermined pulse period, and the other one of the pull-up unit and the pull-down unit pulls-up or pulls-down the second node in response to a second clock signal generated based upon the first clock signal.

12. The flip-flop of claim 11, wherein the pull-down unit comprises:
a second NMOS transistor that operates in response to the first clock signal;
at least one inverter that receives the first clock signal, inverts and delays the first clock signal, and generates a third clock signal; and
a third NMOS transistor that operates in response to the third clock signal and is serially connected to the second NMOS transistor.

13. The flip-flop of claim 11, wherein the pull-up unit comprises:
a second PMOS transistor that operates in response to the first clock signal;
at least one inverter that receives the first clock signal, inverts and delays the first clock signal, and generates a third clock signal; and
a third PMOS transistor that operates in response to the third clock signal and is serially connected to the second PMOS transistor.

14. A method for minimizing flip-flop input-output delay, comprising:
connecting a pull-up unit between a power voltage source and an output node;
connecting a pull-down unit between a ground voltage source and the output node;
applying an input node voltage to the pull-up unit and to the pull-down unit;
applying a clock signal to the pull-up unit and a pulse signal to the pull-down unit; and
latching and outputting a pull-up voltage transferred to the output node by the pull-up unit in response to one of a clock signal and a pulse signal, and latching and outputting a pull-down voltage transferred to the output node by the pull-down unit in response to the other one of the clock signal and the pulse signal.

15. The method of claim 14, further comprising inverting the pull-up voltage or the pull-down voltage transferred to the output node.

16. The method of claim 14, wherein the pulse signal pulse signal is generated using a reference clock and has the same cycle as the clock signal.

17. The method of claim 14, wherein the input node voltage is a pre-charged voltage generated from an external dynamic logic circuit.
